(19) United States
(12) Patent Application Publication
(10) Pub. No.: US 2024/0321346 A1
(43) Pub. Date: Sep. 26, 2024

(54) STATIC RANDOM-ACCESS MEMORY AND INTEGRATED CIRCUIT LAYOUT THEREOF

(71) Applicant: Shanghai Huali Integrated Circuit Corporation, Shanghai (CN)

(72) Inventors: Mu CAO, Shanghai (CN); Koichi KUROKI, Shanghai (CN)

(73) Assignee: Shanghai Huali Integrated Circuit Corporation, Shanghai (CN)

(21) Appl. No.: 18/582,183

(22) Filed: Feb. 20, 2024

(30) Foreign Application Priority Data
Mar. 20, 2023 (CN) 202310280177.0

(51) Int. Cl. G11C 11/413; H10B 10/00

(52) U.S. Cl. CPC G11C 11/413; H10B 10/00

(57) ABSTRACT

The present application discloses a static random-access memory. Upon an entry to a sleep mode, a power switch transistor in a word line drive power supply module is off, thus controlling the elimination of a leakage path of a word line driver, so that leakage power consumption of the SRAM is maintained at that of an on standby state of a normal operating mode or a data retention mode. The entry to and exit from the sleep mode of the SRAM can be carried out flexibly and quickly, without complying with strict timing requirements required by stepwise powering-on and stepwise powering-off, thereby facilitating the implementation of a leakage control function without increasing a layout size. The present application discloses an integrated circuit layout of the static random-access memory.

### CROSS-REFERENCES TO RELATED APPLICATIONS

This application claims the priority to Chinese patent application No. CN202310280177.0, filed on Mar. 20, 2023, and entitled “STATIC RANDOM-ACCESS MEMORY AND INTEGRATED CIRCUIT LAYOUT THEREOF,” the disclosure of which is incorporated herein by reference in entirety.

### TECHNICAL FIELD

The present application relates to the technical field of chip designs, in particular to a static random-access memory and an integrated circuit layout thereof.

### BACKGROUND

Currently, one of the ideas for designing a low power consumption circuit of a Static Random-Access Memory (SRAM) is to cause the SRAM to enter a data retention mode. This mode generally requires the introduction of dual power supplies, that is, a peripheral circuit and a memory array are supplied with power independently of each other. Upon the entry to this mode, a supply voltage is lowered, so as to achieve the purposes of leakage reduction and data retention (e.g., Chinese patent applications 200810096656.2, 201910274520.4, and 202011472173.5). In order to achieve the purposes, the circuit design requires the introduction of a power switch module, a supply voltage boost (or buck) control module, etc. Due to a difference between the peripheral circuit voltage and the memory circuit voltage, the introduction of a word line level shift (level_shift) module etc. is also required. In order to ensure the stability of power supply to the circuit, the introduction of large-sized CMOS transistors into these modules is required, resulting in additional area expansion of SRAM IP (Intellectual Property Core, IP for short), and particularly for small-capacity SRAMs, the area may increase even by more than 50%. Meanwhile, after the SRAM returns to a normal operating mode, and to be in an on standby state, internal logics of these power supply modules as well as drive of a high load signal increase the leakage, thereby increasing power consumption of the SRAM IP. In addition, the entry to and exit from the data retention mode state are required to comply with strict timing requirements (e.g., Chinese patent application 201810737974.6), so as to prevent a phenomenon of an excessive current caused by the simultaneous powering-on of the internal modules of the IP, in which case the state switching time is long and the operation lacks flexibility, so that frequent entries to the data retention mode for the purpose of reducing power consumption cannot be implemented during the practical use of the IP.

As can be seen from the operating principle of the SRAM, the internal leakage power of the IP is mainly concentrated in a word line driver and a memory cell array, and with the increase of the IP capacity, the proportion of leakage power consumption in these two areas increases continuously. For a large-capacity IP, the power consumption proportion can reach more than 90%.

### BRIEF SUMMARY

The technical problem to be solved by the present application is how to facilitate the implementation of a leakage control function of a static random-access memory without increasing a layout size.

In order to solve the above technical problem, the static random-access memory provided by the present application includes a sleep mode control module and a memory cell array module, wherein

each row of the memory cell array module includes M memory cells and one word line driver, M being a positive integer;

the sleep mode control module includes a word line drive power supply module, and the word line drive power supply module includes a power switch transistor;

the word line driver includes a first inverter and a second inverter;

the first inverter has an input end for connecting with a word line decode signal DEC, an output end connected with an input end of the second inverter, a power end connected with an external operating power supply VDD, and a ground end connected with an external ground voltage VSS;

the second inverter has an output end connected with a word line WL of the M memory cells of the corresponding row, a power end connected with a word line drive internal voltage node WL_VDD, and a ground end connected with the external ground voltage VSS;

the power switch transistor of the word line drive power supply module of the sleep mode control module has one end connected with the word line drive internal voltage node WL_VDD and the other end connected with the external operating power supply VDD;

after the static random-access memory enters a sleep mode, a sleep logic enable signal controls the power switch transistor of the word line drive power supply module to be off, so that the power end of the second inverter is disconnected from the external operating power supply VDD, in which case no power is supplied to the second inverter of the word line driver; when the static random-access memory returns to a normal operating mode, the sleep logic enable signal controls the power switch transistor of the word line drive power supply module to be on, so that a power end of the word line driver is connected with the external operating power supply VDD to restore power supply to the second inverter of the word line driver.

In an example, the second inverter includes a first drive PMOS transistor Pd1 and a first drive NMOS transistor Nd1;

a gate end of the first drive PMOS transistor Pd1 and a gate end of the first drive NMOS transistor Nd1 are short-connected to act as the input end of the second inverter;

a drain end of the first drive PMOS transistor Pd1 and a drain end of the first drive NMOS transistor Nd1 are short-connected to act as the output end of the second inverter;

a source end of the first drive NMOS transistor Nd1 acts as the ground end of the second inverter;

a drain end of the first drive PMOS transistor Pd1 acts as the power end of the second inverter.

In an example, the word line drive power supply module includes a zeroth power supply PMOS transistor Ps0, a first power supply PMOS transistor Ps1, a second power supply PMOS transistor Ps2, a zeroth power supply NMOS transistor Ns0, and a first power supply NMOS transistor Ns1;

source ends of the zeroth power supply PMOS transistor Ps0, the first power supply PMOS transistor Ps1, and the second power supply PMOS transistor Ps2 are jointly connected with the external operating power supply VDD, source ends of the zeroth power supply NMOS transistor Ns0 and the first power supply NMOS transistor Ns1 are jointly connected with the external ground voltage VSS, a gate end of the zeroth power supply PMOS transistor Ps0 and a gate end of the zeroth power supply NMOS transistor Ns0 are short-connected to the sleep logic enable signal, a drain end of the zeroth power supply PMOS transistor Ps0 and a drain end of the zeroth power supply NMOS transistor Ns0 are short-connected with a gate end of the first power supply PMOS transistor Ps1 and a gate end of the first power supply NMOS transistor Ns1, and a drain end of the first power supply PMOS transistor Ps1 and a drain end of the first power supply NMOS transistor Ns1 are short-connected with a gate end of the second power supply PMOS transistor Ps2; a drain end of the second power supply PMOS transistor Ps2 is connected with the power end of the second inverter, and the second power supply PMOS transistor Ps2 acts as a power switch to provide power supply control for the second inverter of the word line driver;

after the static random-access memory enters the sleep mode, the sleep logic enable signal is set to a logic “1”, a gate end control signal PWCTRL of the second power supply PMOS transistor Ps2 acting as the power switch transistor is set to the logic “1”, the second power supply PMOS transistor Ps2 is off, and the external operating power supply VDD stops the power supply to the second inverter of the word line driver; upon a return to the normal operating mode, the sleep logic enable signal is set to a logic “0”, the gate end control signal PWCTRL of the second power supply PMOS transistor Ps2 acting as the power switch transistor is set to the logic “0”, the second power supply PMOS transistor Ps2 is on, and the external operating power supply VDD starts the power supply to the second inverter of the word line driver.

In an example, the word line driver further includes a word line potential pull-down control NMOS transistor Nd2;

the sleep mode control module further includes a word line interference isolation module;

the word line potential pull-down control NMOS transistor Nd2 has a drain end connected with the output end of the second inverter and a source end connected with the external ground voltage VSS;

the word line interference isolation module includes a zeroth interference PMOS transistor Pj0, a first interference PMOS transistor Pj1, a zeroth interference NMOS transistor Nj0, and a first interference NMOS transistor Nj1;

source ends of the zeroth interference PMOS transistor Pj0 and the first interference PMOS transistor Pj1 are jointly connected with the external operating power supply VDD, and source ends of the zeroth interference NMOS transistor Nj0 and the first interference NMOS transistor Nj1 are jointly connected with the external ground voltage VSS;

a gate end of the zeroth interference PMOS transistor Pj0 and a gate end of the zeroth interference NMOS transistor Nj0 are short-connected to the sleep logic enable signal, a drain end of the zeroth interference PMOS transistor Pj0 and a drain end of the zeroth interference NMOS transistor Nj0 are short-connected with a gate end of the first interference PMOS transistor Pj1 and a gate end of the first interference NMOS transistor Nj1, and a drain end of the first interference PMOS transistor Pj1 and a drain end of the first interference NMOS transistor Nj1 are short-connected with a gate end of the word line potential pull-down control NMOS transistor Nd2 of the word line driver, so as to generate a control signal WL_SHUT of the word line potential pull-down control NMOS transistor Nd2;

upon an entry to the sleep mode, the sleep logic enable signal is set to a logic “1”, the word line potential pull-down control NMOS transistor Nd2 of the word line driver is on, each word line signal is set to a logic “0”, so as to prevent a pass gate transistor of the memory cell from being on, thereby protecting data inside the memory cell array; upon a return to the normal operating mode, the sleep logic enable signal is set to the logic “0”, and the word line potential pull-down control NMOS transistor Nd2 is off.

In an example, the sleep mode control module further includes a word line drive ground voltage control module;

the first inverter includes a zeroth drive PMOS transistor Pd0 and a zeroth drive NMOS transistor Nd0;

a gate end of the zeroth drive PMOS transistor Pd0 and a gate end of the zeroth drive NMOS transistor Nd0 are short-connected to act as the input end of the first inverter;

a drain end of the zeroth drive PMOS transistor Pd0 and a drain end of the zeroth drive NMOS transistor Nd0 are short-connected to act as the output end of the first inverter;

a source end of the zeroth drive NMOS transistor Nd0 acts as the ground end of the first inverter;

a source end of the zeroth drive PMOS transistor Pd0 acts as the power end of the first inverter;

the first inverter has the input end for connecting with the word line decode signal DEC, the output end connected with the input end of the second inverter, and the power end connected with the external operating power supply VDD;

the word line drive ground voltage control module includes a zeroth drive ground PMOS transistor Pg0, a zeroth drive ground NMOS transistor Ng0, and a first drive ground NMOS transistor Ng1;

a source end of the zeroth drive ground PMOS transistor Pg0 is connected with the external operating power supply VDD, a gate end of the zeroth drive ground PMOS transistor Pg0 and a gate end of the zeroth drive ground NMOS transistor Ng0 are jointly connected with the sleep logic enable signal, a drain end of the zeroth drive ground PMOS transistor Pg0 and a drain end of the zeroth drive ground NMOS transistor Ng0 are jointly connected with a gate end of the first drive ground NMOS transistor Ng1, a source end of the zeroth drive ground NMOS transistor Ng0 and a source end of the first drive ground NMOS transistor Ng1 are connected with the external ground voltage VSS, the source end of ground end of the first drive ground NMOS transistor Ng1 is connected with the ground end of the first inverter of the word line driver, so as to provide a word line drive internal ground voltage WL_VSS for the first inverter of the word line driver.

In an example, the sleep mode control module further includes a memory cell array ground voltage control module;

the memory cell array ground voltage control module includes a zeroth storage ground PMOS transistor Pc0, a zeroth storage ground NMOS transistor Nc0, a first storage ground NMOS transistor Nc1, a second storage ground NMOS transistor Nc2, and a third storage ground NMOS transistor Nc3;

a gate end of the zeroth storage ground PMOS transistor Pc0, a gate end of the zeroth storage ground NMOS transistor Nc0, and a gate end of the second storage ground NMOS transistor Nc2 are jointly connected with the sleep logic enable signal, a source end of the zeroth storage ground PMOS transistor Pc0 is connected with the external operating power supply VDD, a drain end of the zeroth storage ground PMOS transistor Pc0 and a drain end of the zeroth storage ground NMOS transistor Nc0 are jointly connected with a gate end of the first storage ground NMOS transistor Nc1, a source end of the second storage ground NMOS transistor Nc2 is connected with a drain end and a gate end of the third storage ground NMOS transistor Nc3, a source end of the first storage ground NMOS transistor Nc1 and a source end of the third storage ground NMOS transistor Nc3 are jointly connected with the external ground voltage VSS, and a drain end of the first storage ground NMOS transistor Nc1 and a drain end of the second storage ground NMOS transistor Nc2 are short-connected to a ground end VSSCORE of the memory cell.

In an example, the memory cell includes a zeroth transmission NMOS transistor NPG0, a first transmission NMOS transistor NPG1, a zeroth pull-up PMOS transistor PPU0, a first pull-up PMOS transistor PPU1, a zeroth pull-down NMOS transistor NPD0, and a first pull-down NMOS transistor NPD1;

a gate end of the zeroth transmission NMOS transistor NPG0 and a gate end of the first transmission NMOS transistor NPG1 are short-connected to the word line WL, and a drain end of the zeroth transmission NMOS transistor and a drain end of the first transmission NMOS transistor NPG1 are connected with complementary bit lines (BL, BLB);

a source end of the zeroth pull-up PMOS transistor PPU0 and a source of the first pull-up PMOS transistor PPU1 are jointly connected with the external operating power supply VDD, a drain end of the zeroth pull-up PMOS transistor PPU0, a drain end of the zeroth pull-down NMOS transistor NPD0, a gate end of the first pull-up PMOS transistor PPU1, and a gate end of the first pull-down NMOS transistor NPD1 are short-connected to a source end of the zeroth transmission NMOS transistor NPG0, and a gate end of the zeroth pull-up PMOS transistor PPU0, a gate end of the zeroth pull-down NMOS transistor NPD0, a drain end of the first pull-up PMOS transistor PPU1, and a drain end of the first pull-down NMOS transistor NPD1 are short-connected to a source end of the first transmission NMOS transistor NPG1;

the zeroth pull-down NMOS transistor NPD0 and the first pull-down NMOS transistor NPD1 are short-connected to act as a ground end VSSCORE of the memory cell.

In an example, M is 8, 16, 32, or 64.

In order to solve the above technical problem, the present application provides an integrated circuit layout of the static random-access memory, wherein a word line decode TAP area corresponding to a memory cell array trap potential TAP area acts as power switch areas for an external operating power supply VDD and a word line drive internal voltage node WL_VDD and for an external ground voltage VSS and a word line drive internal ground voltage WL_VSS.

In the static random-access memory (SRAM) of the present application, an external sleep enable signal produces an internal sleep logic enable signal by means of the sleep mode control module, which performs logic control of the word line drive power supply module in the sleep mode control module to cause the SRAM to enter a low power consumption state. The word line drive power supply module controls on/off switching of the external operating power supply VDD of the second inverter of the word line driver. After the static random-access memory enters the sleep mode, the sleep logic enable signal controls the power switch (power_switch) transistor of the word line drive power supply module to be off, so that the power end of the second inverter is disconnected from the external operating power supply VDD to stop the power supply, thus eliminating the leakage path. When the static random-access memory returns to the normal operating mode, the sleep logic enable signal controls the power switch (power_switch) transistor of the word line drive power supply module to be on, so that the second inverter of the word line driver is connected with the external operating power supply VDD to restore the power supply. After the static random-access memory enters the sleep mode, the power switch (power_switch) transistor in the word line drive power supply module is off, thus controlling the elimination of the leakage path of the word line driver, so that the leakage power consumption of SRAM is between data retention mode and a standby state of normal operating mode. The entry to and exit from the sleep mode of the SRAM can be carried out flexibly and quickly, without complying with strict timing requirements required by stepwise powering-on and stepwise powering-off, thereby facilitating the implementation of a leakage control function without increasing a layout size.

### BRIEF DESCRIPTION OF THE DRAWINGS

In order to more clearly explain the technical solutions of the present application, the drawings required by the present application will be briefly described below. It is obvious that the drawings described below are merely some embodiments of the present application, and those skilled in the art could also obtain other drawings on the basis of these drawings without the practice of inventive effort.

FIG. 1 is a circuit diagram of a static random-access memory in an embodiment of the present application;

FIG. 2 is a circuit diagram of a word line drive power supply module of the static random-access memory in an embodiment of the present application;

FIG. 3 is a circuit diagram of a word line interference isolation module of the static random-access memory in an embodiment of the present application;

FIG. 4 is a circuit diagram of a word line drive ground voltage control module of the static random-access memory in an embodiment of the present application;

FIG. 5 is a circuit diagram of a memory cell array ground voltage control module of the static random-access memory in an embodiment of the present application;

FIG. 6 is a schematic diagram of a change in an integrated circuit layout of the static random-access memory of the present application; and

FIG. 7 is a schematic diagram of a part of the integrated circuit layout of the static random-access memory of the present application.

### DETAILED DESCRIPTION OF THE DISCLOSURE

The technical solutions in the embodiments of the present application will be clearly and completely described below in conjunction with the drawings. Obviously, the described embodiments are just part of the embodiments of the present application, rather than all of the embodiments. Based on the embodiments in the present application, all other embodiments obtained by those skilled in the art without the practice of inventive effort shall fall into the protection scope of the present application.

The terms such as “first” and “second” used in the present application do not indicate any order, quantity, or importance, but are only used to distinguish different constituent parts. The terms such as “include” or “comprise” mean that the components or objects in front of these terms cover the components or objects listed after the terms and equivalents thereof, without excluding other components or objects. The terms such as “connection” or “coupling” are not limited to physical or mechanical connections, but may include electrical connections, whether direct or indirect. The terms “up”, “down”, “left”, “right”, etc. are only used to represent relative positional relationships, which may vary accordingly after absolute positions of the described objects vary.

It should be noted that the embodiments or features in the embodiments of the present application may be combined with each other in the case of no conflicts.

### Embodiment I

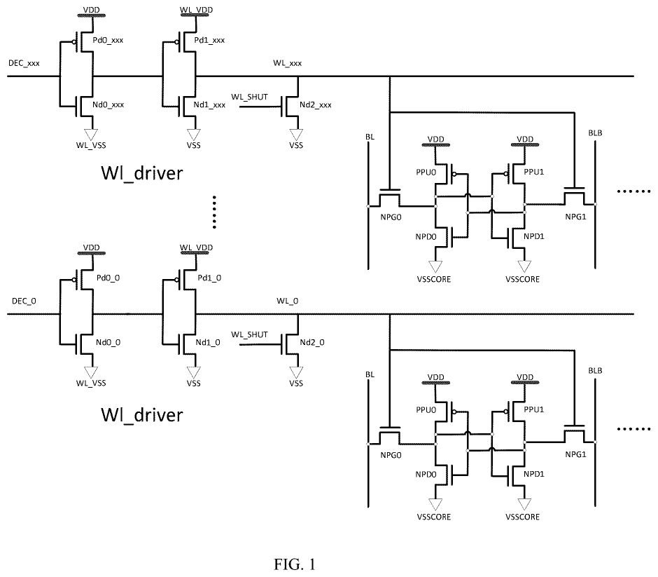

Referring to FIG. 1, a static random-access memory (SRAM) includes a sleep mode control module and a memory cell array module.

Each row of the memory cell array module includes M memory cells and one word line driver (WL_driver), M being a positive integer (e.g., M being 8, 16, 32, or 64).

The sleep mode control module includes a word line drive power supply module, and the word line drive power supply module includes a power switch (power_switch) transistor.

The word line driver includes a first inverter and a second inverter.

The first inverter has an input end for connecting with a word line decode signal DEC, an output end connected with an input end of the second inverter, a power end connected with an external operating power supply VDD, and a ground end connected with an external ground voltage VSS.

The second inverter has an output end connected with a word line WL of the M memory cells of the corresponding row, a power end connected with a word line drive internal voltage node WL_VDD, and a ground end connected with the external ground voltage VSS.

The power switch (power_switch) transistor of the word line drive power supply module of the sleep mode control module has one end connected with the word line drive internal voltage node WL_VDD and the other end connected with the external operating power supply VDD.

After the static random-access memory enters a sleep mode, a sleep logic enable signal controls the power switch (power_switch) transistor of the word line drive power supply module to be off, so that the power end of the second inverter is disconnected from the external operating power supply VDD, in which case no power is supplied to the second inverter of the word line driver and a leakage path is eliminated; when the static random-access memory returns to a normal operating mode, the sleep logic enable signal controls the power switch (power_switch) transistor of the word line drive power supply module to be on, so that a power end of the word line driver is connected with the external operating power supply VDD to restore power supply to the second inverter of the word line driver.

In the static random-access memory (SRAM) of Embodiment I, an external sleep enable signal produces an internal sleep logic enable signal by means of the sleep mode control module, which performs logic control of the word line drive power supply module in the sleep mode control module to cause the SRAM to enter a low power consumption state. The word line drive power supply module controls on/off switching of the external operating power supply VDD of the second inverter of the word line driver. After the static random-access memory enters the sleep mode, the sleep logic enable signal controls the power switch (power_switch) transistor of the word line drive power supply module to be off, so that the power end of the second inverter is disconnected from the external operating power supply VDD to stop the power supply, thus eliminating the leakage path. When the static random-access memory returns to the normal operating mode, the sleep logic enable signal controls the power switch (power_switch) transistor of the word line drive power supply module to be on, so that the second inverter of the word line driver is connected with the external operating power supply VDD to restore the power supply.

After the static random-access memory (SRAM) of Embodiment I enters the sleep mode, the power switch (power_switch) transistor in the word line drive power supply module is off, thus controlling the elimination of the leakage path of the word line driver, so that the leakage power consumption of SRAM is between data retention mode and a standby state of normal operating mode. The entry to and exit from the sleep mode of the SRAM can be carried out flexibly and quickly, without complying with strict timing requirements required by stepwise powering-on and stepwise powering-off, thereby facilitating the implementation of a leakage control function without increasing a layout size.

### Embodiment II

Based on the static random-access memory of Embodiment I, referring to FIG. 1, the second inverter includes a first drive PMOS transistor Pd1 and a first drive NMOS transistor Nd1.

A gate end of the first drive PMOS transistor Pd1 and a gate end of the first drive NMOS transistor Nd1 are short-connected to act as the input end of the second inverter.

A drain end of the first drive PMOS transistor Pd1 and a drain end of the first drive NMOS transistor Nd1 are short-connected to act as the output end of the second inverter.

A source end of the first drive NMOS transistor Nd1 acts as the ground end of the second inverter.

A drain end of the first drive PMOS transistor Pd1 acts as the power end of the second inverter.

### Embodiment III

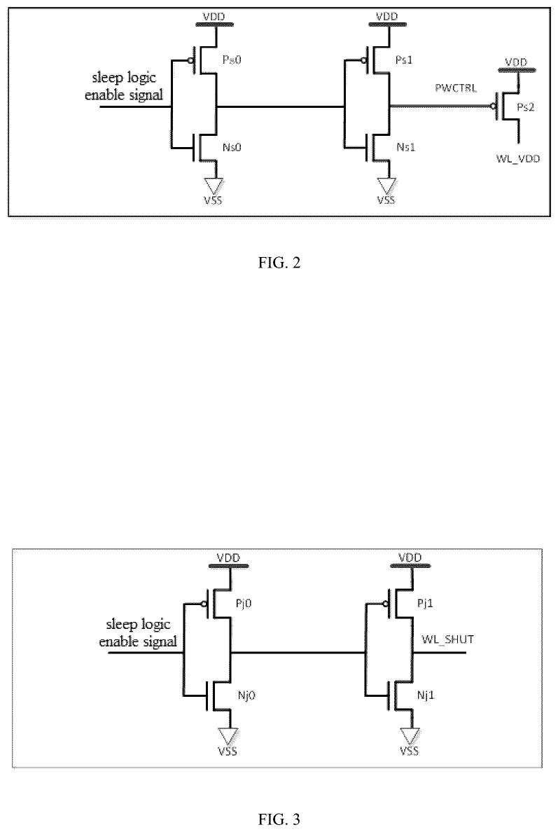

Based on the static random-access memory (SRAM) of Embodiment II, referring to FIG. 2, the word line drive power supply module includes a zeroth power supply PMOS transistor Ps0, a first power supply PMOS transistor Ps1, a second power supply PMOS transistor Ps2, a zeroth power supply NMOS transistor Ns0, and a first power supply NMOS transistor Ns1.

Source ends of the zeroth power supply PMOS transistor Ps0, the first power supply PMOS transistor Ps1, and the second power supply PMOS transistor Ps2 are jointly connected with the external operating power supply VDD, source ends of the zeroth power supply NMOS transistor Ns0 and the first power supply NMOS transistor Ns1 are jointly connected with the external ground voltage VSS, a gate end of the zeroth power supply PMOS transistor Ps0 and a gate end of the zeroth power supply NMOS transistor Ns0 are short-connected to the sleep logic enable signal, a drain end of the zeroth power supply PMOS transistor Ps0 and a drain end of the zeroth power supply NMOS transistor Ns0 are short-connected with a gate end of the first power supply PMOS transistor Ps1 and a gate end of the first power supply NMOS transistor Ns1, and a drain end of the first power supply PMOS transistor Ps1 and a drain end of the first power supply NMOS transistor Ns1 are short-connected with a gate end of the second power supply PMOS transistor Ps2; a drain end of the second power supply PMOS transistor Ps2 is connected with the power end of the second inverter, and the second power supply PMOS transistor Ps2 acts as a power switch (power_switch) transistor to provide power supply control for the second inverter of the word line driver;

After the static random-access memory enters the sleep mode, the sleep logic enable signal is set to a logic “1” (high level), a gate end control signal PWCTRL of the second power supply PMOS transistor Ps2 acting as the power switch (power_switch) transistor is set to the logic “1” (high level), the second power supply PMOS transistor Ps2 is off, and the external operating power supply VDD stops the power supply to the second inverter of the word line driver, eliminating the leakage path of the second inverter of the word line driver; upon a return to the normal operating mode, the sleep logic enable signal is set to a logic “0” (low level), the gate end control signal PWCTRL of the second power supply PMOS transistor Ps2 acting as the power switch (power switch) transistor is set to the logic “0” (low level), the second power supply PMOS transistor Ps2 is on, and the external operating power supply VDD starts the power supply to the second inverter of the word line driver.

### Embodiment IV

Based on the static random-access memory (SRAM) of Embodiment I, the word line driver further includes a word line potential pull-down control NMOS transistor Nd2.

The sleep mode control module further includes a word line interference isolation module.

The word line potential pull-down control NMOS transistor Nd2 has a drain end connected with the output end of the second inverter and a source end connected with the external ground voltage VSS.

Referring to FIG. 3, the word line interference isolation module includes a zeroth interference PMOS transistor Pj0, a first interference PMOS transistor Pj1, a zeroth interference NMOS transistor Nj0, and a first interference NMOS transistor Nj1.

Source ends of the zeroth interference PMOS transistor Pj0 and the first interference PMOS transistor Pj1 are jointly connected with the external operating power supply VDD, and source ends of the zeroth interference NMOS transistor Nj0 and the first interference NMOS transistor Nj1 are jointly connected with the external ground voltage VSS.

A gate end of the zeroth interference PMOS transistor Pj0 and a gate end of the zeroth interference NMOS transistor Nj0 are short-connected to the sleep logic enable signal, a drain end of the zeroth interference PMOS transistor Pj0 and a drain end of the zeroth interference NMOS transistor Nj0 are short-connected with a gate end of the first interference PMOS transistor Pj1 and a gate end of the first interference NMOS transistor Nj1, and a drain end of the first interference PMOS transistor Pj1 and a drain end of the first interference NMOS transistor Nj1 are short-connected with a gate end of the word line potential pull-down control NMOS transistor Nd2 of the word line driver, so as to generate a control signal WL_SHUT of the word line potential pull-down control NMOS transistor Nd2.

Upon an entry to the sleep mode, the sleep logic enable signal is set to a logic “1”, the word line potential pull-down control NMOS transistor Nd2 of the word line driver is on, each word line signal is set to a logic “0”, so as to prevent a pass gate (pass gate) transistor of the memory cell (bitcell) from being on, thereby protecting data inside the memory cell array; upon a return to the normal operating mode, the sleep logic enable signal is set to the logic “0”, and the word line potential pull-down control NMOS transistor Nd2 is off, and the word line restores a normal decoding function.

In the static random-access memory of Embodiment IV, the word line potential pull-down control NMOS transistor Nd2 is controlled to be on and off through the word line interference isolation module. After the static random-access memory enters the sleep mode, the sleep logic enable signal controls the word line potential pull-down NMOS transistor to be on, each word line signal is set to the logic “0”, so as to prohibit each word line from being at the high level in the sleep mode, thereby preventing tampering of the data inside the memory cell array and protecting the data inside the memory cell array. Upon the return to the normal operating mode, the word line potential pull-down NMOS transistor is off, and the word line restores a normal decoding function.

### Embodiment V

Based on the static random-access memory (SRAM) of Embodiment I, the sleep mode control module further includes a word line drive ground voltage control module.

Referring to FIG. 1, the first inverter includes a zeroth drive PMOS transistor Pd0 and a zeroth drive NMOS transistor Nd0.

A gate end of the zeroth drive PMOS transistor Pd0 and a gate end of the zeroth drive NMOS transistor Nd are short-connected to act as the input end of the first inverter.

A drain end of the zeroth drive PMOS transistor Pd0 and a drain end of the zeroth drive NMOS transistor Nd0 are short-connected to act as the output end of the first inverter.

A source end of the zeroth drive NMOS transistor Nd0 acts as the ground end of the first inverter.

A source end of the zeroth drive PMOS transistor Pd0 acts as the power end of the first inverter.

The first inverter has the input end for connecting with the word line decode signal DEC, the output end connected with the input end of the second inverter, and the power end connected with the external operating power supply VDD.

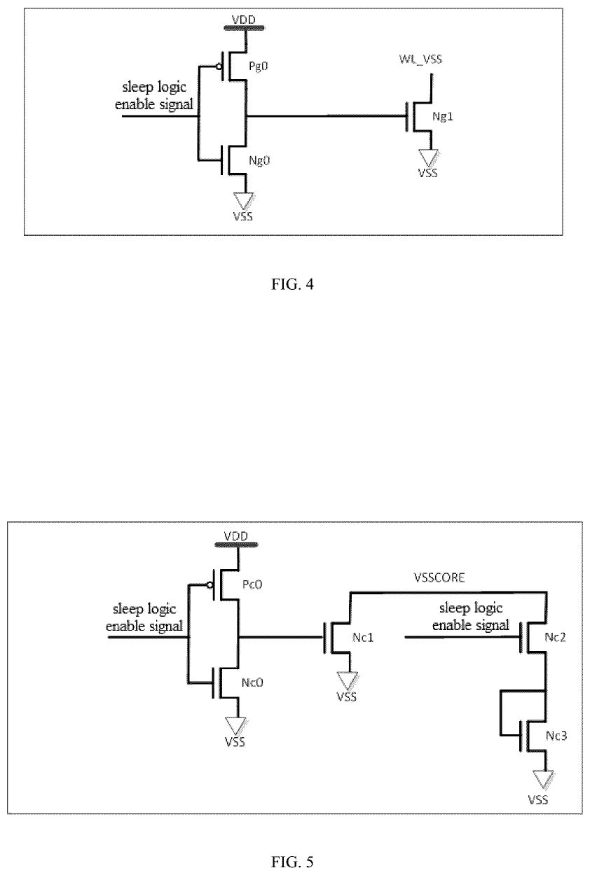

Referring to FIG. 4, the word line drive ground voltage control module includes a zeroth drive ground PMOS transistor Pg0, a zeroth drive ground NMOS transistor Ng0, and a first drive ground NMOS transistor Ng1.

A source end of the zeroth drive ground PMOS transistor Pg0 is connected with the external operating power supply VDD, a gate end of the zeroth drive ground PMOS transistor Pg0 and a gate end of the zeroth drive ground NMOS transistor Ng0 are jointly connected with the sleep logic enable signal, a drain end of the zeroth drive ground PMOS transistor Pg0 and a drain end of the zeroth drive ground NMOS transistor Ng0 are jointly connected with a gate end of the first drive ground NMOS transistor Ng1, a source end of the zeroth drive ground NMOS transistor Ng0 and a source end of the first drive ground NMOS transistor Ng1 are connected with the external ground voltage VSS, the source end of ground end of the first drive ground NMOS transistor Ng1 is connected with the ground end of the first inverter of the word line driver, so as to provide a word line drive internal ground voltage WL_VSS for the first inverter of the word line driver.

In the static random-access memory (SRAM) of Embodiment V, the word line drive ground voltage control module provides a power switch (power_switch) function for the word line drive internal ground voltage WL_VSS of the first inverter of the word line driver, so as to perform power supply control of the word line drive internal ground voltage WL_VSS of the first inverter of the word line driver. Upon an entry to the sleep mode, the sleep logic enable signal is set to the logic “1”, the first drive ground NMOS transistor Ng1 acting as a power switch (power_switch) transistor in FIG. 4 is off, and the word line drive internal ground voltage WL_VSS is disconnected from the external ground voltage VSS, so as to eliminate a leakage path of this stage drive. Upon a return to the normal operating mode, the sleep logic enable signal is set to the logic “0”, the first drive ground NMOS transistor Ng1 acting as the power switch (power_switch) transistor in FIG. 4 is on, and the word line drive internal ground voltage WL_VSS is connected with the external ground voltage VSS, thereby restoring a word line drive function.

### Embodiment VI

Based on the static random-access memory (SRAM) of Embodiment I, the sleep mode control module further includes a memory cell array ground voltage control module.

Referring to FIG. 5, the memory cell array ground voltage control module includes a zeroth storage ground PMOS transistor Pc0, a zeroth storage ground NMOS transistor Nc0, a first storage ground NMOS transistor Nc1, a second storage ground NMOS transistor Nc2, and a third storage ground NMOS transistor Nc3.

A gate end of the zeroth storage ground PMOS transistor Pc0, a gate end of the zeroth storage ground NMOS transistor Nc0, and a gate end of the second storage ground NMOS transistor Nc2 are jointly connected with the sleep logic enable signal, a source end of the zeroth storage ground PMOS transistor Pc0 is connected with the external operating power supply VDD, a drain end of the zeroth storage ground PMOS transistor Pc0 and a drain end of the zeroth storage ground NMOS transistor Nc0 are jointly connected with a gate end of the first storage ground NMOS transistor Nc1, a source end of the second storage ground NMOS transistor Nc2 is connected with a drain end and a gate end of the third storage ground NMOS transistor Nc3, a source end of the first storage ground NMOS transistor Nc1 and a source end of the third storage ground NMOS transistor Nc3 are jointly connected with the external ground voltage VSS, and a drain end of the first storage ground NMOS transistor Nc1 and a drain end of the second storage ground NMOS transistor Nc2 are short-connected to a ground end VSSCORE of the memory cell.

In an example, the memory cell includes a zeroth transmission NMOS transistor NPG0, a first transmission NMOS transistor NPG1, a zeroth pull-up PMOS transistor PPU0, a first pull-up PMOS transistor PPU1, a zeroth pull-down NMOS transistor NPD0, and a first pull-down NMOS transistor NPD1.

A gate end of the zeroth transmission NMOS transistor NPG0 and a gate end of the first transmission NMOS transistor NPG1 are short-connected to the word line WL, and a drain end of the zeroth transmission NMOS transistor and a drain end of the first transmission NMOS transistor NPG1 are connected with complementary bit lines (BL, BLB).

A source end of the zeroth pull-up PMOS transistor PPU0 and a source of the first pull-up PMOS transistor PPU1 are jointly connected with the external operating power supply VDD, a drain end of the zeroth pull-up PMOS transistor PPU0, a drain end of the zeroth pull-down NMOS transistor NPD0, a gate end of the first pull-up PMOS transistor PPU1, and a gate end of the first pull-down NMOS transistor NPD1 are short-connected to a source end of the zeroth transmission NMOS transistor NPG0, and a gate end of the zeroth pull-up PMOS transistor PPU0, a gate end of the zeroth pull-down NMOS transistor NPD0, a drain end of the first pull-up PMOS transistor PPU1, and a drain end of the first pull-down NMOS transistor NPD1 are short-connected to a source end of the first transmission NMOS transistor NPG1.

The gate end of zeroth pull-down NMOS transistor NPD0 and the gate end of first pull-down NMOS transistor NPD1 are short-connected to act as a ground end VSSCORE of the memory cell.

In the static random-access memory (SRAM) of Embodiment VI, a voltage state of a ground voltage signal at the source (S) end of the pull-down (pull_down) transistor (NPD) of the memory cell is controlled through the memory cell array ground voltage control module. Upon an entry to the sleep mode, the sleep logic enable signal logic is set to the logic “1”, the first storage ground NMOS tube Nc1 in FIG. 5 is off, and the second storage ground NMOS transistor Nc2 is on, in which case the ground end VSSCORE voltage of the memory cell is boosted by the third storage ground NMOS transistor Nc3 to tens or hundreds of millivolts, thereby reducing a voltage drop of the memory cell array to reduce the leakage power consumption. Upon a return to the normal operating mode, the sleep logic enable signal logic is set to the logic “0”, the first storage ground NMOS transistor Nc1 in FIG. 5 is on, and the second storage ground NMOS transistor Nc2 is off, in which case the ground end VSSCORE of the memory cell is connected with the external ground voltage VSS, thereby restoring power supply to the memory cell to a normal operating mode. After the static random-access memory (SRAM) enters the sleep mode, the memory cell array ground voltage control module controls a ground end voltage signal of the pull-down (pull_down) transistor of the memory cell to boost to reduce the voltage drop of the memory cell array, thereby reducing the leakage power consumption.

In the static random-access memory of Embodiment VI, after the sleep logic enable signal logic is set to the high level “1”, the word line drive power supply module, the word line interference isolation module, the word line drive ground voltage control module, and the memory cell array ground voltage control module enter operating states, the memory cell array ground voltage VSSCORE is boosted to about 200 millivolts, in which case the SRAM enters the low power consumption state. The static random-access memory, under a typical process corner, has a stable leakage current of 76.9 uA in the normal operating state; and after entering the sleep mode, has a stable leakage current of 28.1 uA, with a leakage power consumption decrease of about 63.5%.

### Embodiment VII

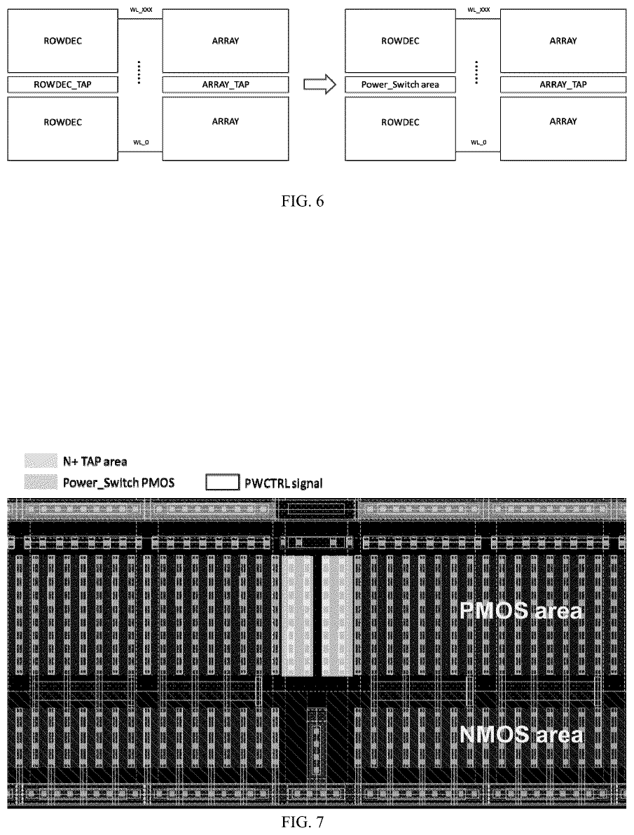

In an integrated circuit layout of the static random-access memory (SRAM) of Embodiment I to Embodiment VI, referring to FIG. 6, a word line decode (ROWDEC) TAP area corresponding to a memory cell array (ARRAY) trap potential TAP area acts as power switch (power_switch) areas for an external operating power supply VDD and a word line drive internal voltage node WL_VDD and for an external ground voltage VSS and a word line drive internal ground voltage WL_VSS.

A PMOS that realizes the switching between the external operating power supply VDD and the word line drive internal voltage node WL_VDD is disposed in a TAP area that provides a potential for a PMOS substrate in a word line decode module corresponding to the memory cell array trap potential TAP area.

An NMOS that realizes the switching between the external ground voltage VSS and the word line drive internal ground voltage WL_VSS is disposed in a TAP area that provides a potential for an NMOS substrate in the word line decode module corresponding to the memory cell array trap potential TAP area.

Referring to FIG. 7, the power switch (power_switch) area for the external operating power supply VDD and the word line drive internal voltage node WL_VDD is formed by deleting an N+TAP area (N+ ion implantation area) that provides the potential for the PMOS substrate between two adjacent word line driver (WL_driver) areas in the word line decode module, extending PMOS areas on both sides thereof, and disposing the power switch (power_switch) PMOS in an extended area. Similarly, the power switch (power_switch) for the external ground voltage VSS and the word line drive internal ground voltage WL_VSS is formed by deleting a P-TAP area (P-ion implantation area) that provides the potential for the NMOS substrate between two adjacent word line driver (WL_driver) areas in the word line decode module, extending NMOS areas on both sides thereof, and disposing the power switch (power_switch) NMOS in an extended area. As such, there are no any increases in the size of the static random-access memory IP.

In an optimized layout design of the integrated circuit layout of the static random-access memory of Embodiment VII, in the word line decode TAP area corresponding to the memory cell array trap potential TAP area, the power switch (power_switch) areas for the external operating power supply VDD and the word line drive internal voltage node WL_VDD and for the external ground voltage VSS and the word line drive internal ground voltage WL_VSS are provided, without producing any area overhead. The power switch (power_switch) areas are uniformly distributed periodically throughout a layout of the word line decode module, achieving low power consumption powering-off and stable powering-on in normal operation of a word line drive area, preventing the SRAM IP from producing additional power switch function area overhead due to the presence of the power switch (power_switch) transistors in the word line drive power supply module and the word line drive ground voltage control module, and implementing the leakage control function without increasing the layout size.

The above descriptions are merely examples of the embodiments of the present application and are not intended to limit the present application. Any modifications, equivalent substitutions, improvements, etc. made within the spirit and principles of the present application shall be included within the protection scope of the present application.

What is claimed is:

1. A static random-access memory, comprising a sleep mode control module and a memory cell array module, wherein
each row of the memory cell array module comprises M memory cells and one word line driver, M being a positive integer;
the sleep mode control module comprises a word line drive power supply module, and the word line drive power supply module comprises a power switch transistor;
the word line driver comprises a first inverter and a second inverter;
the first inverter has an input end for connecting with a word line decode signal (DEC), an output end connected with an input end of the second inverter, a power end connected with an external operating power supply (VDD), and a ground end connected with an external ground voltage (VSS);
the second inverter has an output end connected with a word line (WL) of the M memory cells of the corresponding row, a power end connected with a word line drive internal voltage node (WL_VDD), and a ground end connected with the external ground voltage (VSS);
the power switch transistor of the word line drive power supply module of the sleep mode control module has one end connected with the word line drive internal voltage node (WL_VDD) and the other end connected with the external operating power supply (VDD); and
after the static random-access memory enters a sleep mode, a sleep logic enable signal controls the power switch transistor of the word line drive power supply module to be off, so that the power end of the second inverter is disconnected from the external operating power supply (VDD), in which case no power is supplied to the second inverter of the word line driver; when the static random-access memory returns to a normal operating mode, the sleep logic enable signal controls the power switch transistor of the word line drive power supply module to be on, so that a power end of the word line driver is connected with the external operating power supply (VDD) to restore power supply to the second inverter of the word line driver.

2. The static random-access memory according to claim 1, wherein
the second inverter comprises a first drive PMOS transistor (Pd1) and a first drive NMOS transistor (Nd1);
a gate end of the first drive PMOS transistor (Pd1) and a gate end of the first drive NMOS transistor (Nd1) are short-connected to act as the input end of the second inverter;
a drain end of the first drive PMOS transistor (Pd1) and a drain end of the first drive NMOS transistor (Nd1) are short-connected to act as the output end of the second inverter;
a source end of the first drive NMOS transistor (Nd1) acts as the ground end of the second inverter; and
a drain end of the first drive PMOS transistor (Pd1) acts as the power end of the second inverter.

3. The static random-access memory according to claim 1, wherein
the word line drive power supply module comprises a zeroth power supply PMOS transistor (Ps0), a first power supply PMOS transistor (Ps1), a second power supply PMOS transistor (Ps2), a zeroth power supply NMOS transistor (Ns0), and a first power supply NMOS transistor (Ns1);
source ends of the zeroth power supply PMOS transistor (Ps0), the first power supply PMOS transistor (Ps1), and the second power supply PMOS transistor (Ps2) are jointly connected with the external operating power supply (VDD), source ends of the zeroth power supply NMOS transistor (Ns0) and the first power supply NMOS transistor (Ns1) are jointly connected with the external ground voltage (VSS), a gate end of the zeroth power supply PMOS transistor (Ps0) and a gate end of the zeroth power supply NMOS transistor (Ns0) are short-connected to the sleep logic enable signal, a drain end of the zeroth power supply PMOS transistor (Ps0) and a drain end of the zeroth power supply NMOS transistor (Ns0) are short-connected with a gate end of the first power supply PMOS transistor (Ps1) and a gate end of the first power supply NMOS transistor (Ns1), and a drain end of the first power supply PMOS transistor (Ps1) and a drain end of the first power supply NMOS transistor (Ns1) are short-connected with a gate end of the second power supply PMOS transistor (Ps2); a drain end of the second power supply PMOS transistor (Ps2) is connected with the power end of the second inverter, and the second power supply PMOS transistor (Ps2) acts as a power switch to provide power supply control for the second inverter of the word line driver; and
after the static random-access memory enters the sleep mode, the sleep logic enable signal is set to a logic “1”, a gate end control signal (PWCTRL) of the second power supply PMOS transistor (Ps2) acting as the power switch transistor is set to the logic “1”, the second power supply PMOS transistor (Ps2) is off, and the external operating power supply (VDD) stops the power supply to the second inverter of the word line driver; upon a return to the normal operating mode, the sleep logic enable signal is set to a logic “0”, the gate end control signal (PWCTRL) of the second power supply PMOS transistor (Ps2) acting as the power switch transistor is set to the logic “0”, the second power supply PMOS transistor (Ps2) is on, and the external operating power supply (VDD) starts the power supply to the second inverter of the word line driver.

4. The static random-access memory according to claim 1, wherein
the word line driver further comprises a word line potential pull-down control NMOS transistor (Nd2);
the sleep mode control module further comprises a word line interference isolation module;
the word line potential pull-down control NMOS transistor (Nd2) has a drain end connected with the output end of the second inverter and a source end connected with the external ground voltage (VSS);
the word line interference isolation module comprises a zeroth interference PMOS transistor (Pj0), a first interference PMOS transistor (Pj1), a zeroth interference NMOS transistor (Nj0), and a first interference NMOS transistor (Nj1);
source ends of the zeroth interference PMOS transistor (Pj0) and the first interference PMOS transistor (Pj1) are jointly connected with the external operating power supply (VDD), and source ends of the zeroth interference NMOS transistor (Nj0) and the first interference NMOS transistor (Nj1) are jointly connected with the external ground voltage (VSS);
a gate end of the zeroth interference PMOS transistor (Pj0) and a gate end of the zeroth interference NMOS transistor (Nj0) are short-connected to the sleep logic enable signal, a drain end of the zeroth interference PMOS transistor (Pj0) and a drain end of the zeroth interference NMOS transistor (Nj0) are short-connected with a gate end of the first interference PMOS transistor (Pj1) and a gate end of the first interference NMOS transistor (Nj1), and a drain end of the first interference PMOS transistor (Pj1) and a drain end of the first interference NMOS transistor (Nj1) are short-connected with a gate end of the word line potential pull-down control NMOS transistor (Nd2) of the word line driver, so as to generate a control signal (WL_SHUT) of the word line potential pull-down control NMOS transistor (Nd2); and
upon an entry to the sleep mode, the sleep logic enable signal is set to a logic “1”, the word line potential pull-down control NMOS transistor (Nd2) of the word line driver is on, each word line signal is set to a logic “0”, so as to prevent a pass gate transistor of the memory cell from being on, thereby protecting data inside the memory cell array; upon a return to the normal operating mode, the sleep logic enable signal is set to the logic “0”, and the word line potential pull-down control NMOS transistor (Nd2) is off.

5. The static random-access memory according to claim 1, wherein
the sleep mode control module further comprises a word line drive ground voltage control module;
the first inverter comprises a zeroth drive PMOS transistor (Pd0) and a zeroth drive NMOS transistor (Nd0);
a gate end of the zeroth drive PMOS transistor (Pd0) and a gate end of the zeroth drive NMOS transistor (Nd0) are short-connected to act as the input end of the first inverter;
a drain end of the zeroth drive PMOS transistor (Pd0) and a drain end of the zeroth drive NMOS transistor (Nd0) are short-connected to act as the output end of the first inverter;
a source end of the zeroth drive NMOS transistor (Nd0) acts as the ground end of the first inverter;
a source end of the zeroth drive PMOS transistor (Pd0) acts as the power end of the first inverter;
the first inverter has the input end for connecting with the word line decode signal (DEC), the output end connected with the input end of the second inverter, and the power end connected with the external operating power supply (VDD);
the word line drive ground voltage control module comprises a zeroth drive ground PMOS transistor (Pg0), a zeroth drive ground NMOS transistor (Ng0), and a first drive ground NMOS transistor (Ng1); and
a source end of the zeroth drive ground PMOS transistor (Pg0) is connected with the external operating power supply (VDD), a gate end of the zeroth drive ground PMOS transistor (Pg0) and a gate end of the zeroth drive ground NMOS transistor (Ng0) are jointly connected with the sleep logic enable signal, a drain end of the zeroth drive ground PMOS transistor (Pg0) and a drain end of the zeroth drive ground NMOS transistor (Ng0) are jointly connected with a gate end of the first drive ground NMOS transistor (Ng1), a source end of the zeroth drive ground NMOS transistor (Ng0) and a source end of the first drive ground NMOS transistor (Ng1) are connected with the external ground voltage (VSS), the source end of ground end of the first drive ground NMOS transistor (Ng1) is connected with the ground end of the first inverter of the word line driver, so as to provide a word line drive internal ground voltage (WL_VSS) for the first inverter of the word line driver.

6. The static random-access memory according to claim 1, wherein
the sleep mode control module further comprises a memory cell array ground voltage control module;
the memory cell array ground voltage control module comprises a zeroth storage ground PMOS transistor (Pc0), a zeroth storage ground NMOS transistor (Nc0), a first storage ground NMOS transistor (Nc1), a second storage ground NMOS transistor (Nc2), and a third storage ground NMOS transistor (Nc3); and
a gate end of the zeroth storage ground PMOS transistor (Pc0), a gate end of the zeroth storage ground NMOS transistor (Nc0), and a gate end of the second storage ground NMOS transistor (Nc2) are jointly connected with the sleep logic enable signal, a source end of the zeroth storage ground PMOS transistor (Pc0) is connected with the external operating power supply (VDD), a drain end of the zeroth storage ground PMOS transistor (Pc0) and a drain end of the zeroth storage ground NMOS transistor (Nc0) are jointly connected with a gate end of the first storage ground NMOS transistor (Nc1), a source end of the second storage ground NMOS transistor (Nc2) is connected with a drain end and a gate end of the third storage ground NMOS transistor (Nc3), a source end of the first storage ground NMOS transistor (Nc1) and a source end of the third storage ground NMOS transistor (Nc3) are jointly connected with the external ground voltage (VSS), and a drain end of the first storage ground NMOS transistor (Nc1) and a drain end of the second storage ground NMOS transistor (Nc2) are short-connected to a ground end (VSSCORE) of the memory cell.

7. The static random-access memory according to claim 1, wherein
the memory cell comprises a zeroth transmission NMOS transistor (NPG0), a first transmission NMOS transistor (NPG1), a zeroth pull-up PMOS transistor (PPU0), a first pull-up PMOS transistor (PPU1), a zeroth pull-down NMOS transistor (NPD0), and a first pull-down NMOS transistor (NPD1);
a gate end of the zeroth transmission NMOS transistor (NPG0) and a gate end of the first transmission NMOS transistor (NPG1) are short-connected to the word line (WL), and a drain end of the zeroth transmission NMOS transistor and a drain end of the first transmission NMOS transistor (NPG1) are connected with complementary bit lines (BL, BLB);
a source end of the zeroth pull-up PMOS transistor (PPU0) and a source of the first pull-up PMOS transistor (PPU1) are jointly connected with the external operating power supply (VDD), a drain end of the zeroth pull-up PMOS transistor (PPU0), a drain end of the zeroth pull-down NMOS transistor (NPD0), a gate end of the first pull-up PMOS transistor (PPU1), and a gate end of the first pull-down NMOS transistor (NPD1) are short-connected to a source end of the zeroth transmission NMOS transistor (NPG0), and a gate end of the zeroth pull-up PMOS transistor (PPU0), a gate end of the zeroth pull-down NMOS transistor (NPD0), a drain end of the first pull-up PMOS transistor (PPU1), and a drain end of the first pull-down NMOS transistor (NPD1) are short-connected to a source end of the first transmission NMOS transistor (NPG1); and
the zeroth pull-down NMOS transistor (NPD0) and the first pull-down NMOS transistor (NPD1) are short-connected to act as a ground end (VSSCORE) of the memory cell.

8. The static random-access memory according to claim 1, wherein M is 8, 16, 32, or 64.

9. An integrated circuit layout of the static random-access memory according to claim 5, wherein a word line decode TAP area corresponding to a memory cell array trap potential TAP area acts as power switch areas for an external operating power supply (VDD) and a word line drive internal voltage node (WL_VDD) and for an external ground voltage (VSS) and a word line drive internal ground voltage (WL_VSS).
